(19) United States
(12) Patent Application Publication
(10) Pub. No.: US 2014/0015035 A1
(43) Pub. Date: Jan. 16, 2014

(54) SEMICONDUCTOR DEVICE HAVING VERTICAL TRANSISTOR

(71) Applicant: Elpida Memory, Inc., Tokyo (JP)

(72) Inventor: Yoshihiro TAKAISHI, Tokyo (JP)

(21) Appl. No.: 13/935,046

(22) Filed: Jul. 3, 2013

(30) Foreign Application Priority Data
Jul. 12, 2012 (JP) 2012-156444

(51) Int. Cl. H01L 29/78

(52) U.S. Cl. CPC H01L 29/7827
USPC 257/329

(57) ABSTRACT

Disclosed herein is a semiconductor device that includes: a semiconductor pillar projecting from a main surface of the semiconductor substrate, the semiconductor pillar having a first side surface extending in a first direction that is parallel to the main surface of the semiconductor substrate and a second side surface extending in a second direction crossing to the first direction and parallel to the main surface of the semiconductor substrate; a first impurity diffusion layer formed in an upper portion of the semiconductor pillar; a second impurity diffusion layer formed in the semiconductor substrate near a lower portion of the semiconductor pillar; an insulating pillar covering the first side surface; and a gate electrode covering the second side surface with an intervention of a gate insulating film. A width in the first direction of the semiconductor pillar is narrowed at the first side surface.

### BACKGROUND OF THE INVENTION

1. Field of the Invention

The present invention relates to a semiconductor device, and more particularly relates to a semiconductor device using a transistor having a pillar structure.

2. Description of Related Art

In a semiconductor device, a vertical transistor is adopted for high integration. A vertical transistor includes a gate insulating film and a gate electrode that are formed on a side surface of a semiconductor pillar provided upwardly on a semiconductor substrate. The vertical transistor constitutes a unit transistor with diffusion layers provided on both sides in a vertical direction of the semiconductor pillar. For example, Japanese Patent Application Laid-open No. 2011-23483 describes a vertical transistor that adopts a configuration in which a gate electrode surrounds a composite pillar including a semiconductor pillar and an insulating pillar.

In this type of conventional vertical transistor, when a contact plug that supplies an input signal to a gate electrode is provided in a position that is overlapped with a diffusion layer provided under a semiconductor pillar in a plan view, if a displacement occurs, the contact plug reaches the diffusion layer and is then short-circuited. Accordingly, it is advantageous to provide the contact plug in a position that is overlapped with an element isolation region. Therefore, it is necessary that an insulating pillar provided in the element isolation region contacts the semiconductor pillar, and the gate electrode provided on a side surface of the semiconductor pillar is extended to the element isolation region.

However, there is a problem that at an end of the semiconductor pillar, as a contact part to the insulating pillar, because a part of an insulating film constituting the insulating pillar functions as a gate insulating film, the controllability of a gate potential is degraded to reduce a threshold voltage Vth and a semiconductor device fails to stably operate.

### SUMMARY

In one embodiment, there is provided a semiconductor device that includes: a semiconductor pillar projecting from a main surface of the semiconductor substrate, the semiconductor pillar having a first side surface extending in a first direction that is parallel to the main surface of the semiconductor substrate and a second side surface extending in a second direction crossing to the first direction and parallel to the main surface of the semiconductor substrate; a first impurity diffusion layer formed in an upper portion of the semiconductor pillar; a second impurity diffusion layer formed in the semiconductor substrate near a lower portion of the semiconductor pillar; a first insulating pillar covering the first side surface of the semiconductor pillar; and a first gate electrode covering the second side surface of the semiconductor pillar with an intervention of a first gate insulating film. A width in the first direction of the semiconductor pillar is narrowed at the first side surface.

In another embodiment, there is provided a semiconductor device that includes: a semiconductor pillar projecting from a main surface of the semiconductor substrate; a first impurity diffusion layer formed in an upper portion of the semiconductor pillar; a second impurity diffusion layer formed in the semiconductor substrate near a lower portion of the semiconductor pillar; a first insulating pillar that is in contact with the semiconductor pillar; and a first gate electrode covering a first side surface of the semiconductor pillar with an intervention of a first gate insulating film. The semiconductor pillar includes a first portion and a second portion located between the first portion and the first insulating pillar, the second portion has a different impurity concentration from the first portion.

As described above, according to the present invention, a threshold voltage adjustment region is provided on an end of a semiconductor pillar that contacts an end of an insulating pillar. Therefore, due to the complete depletion of the end of the semiconductor pillar, a reduction in a threshold voltage Vth can be prevented and a semiconductor device can stably operate.

### BRIEF DESCRIPTION OF THE DRAWINGS

FIG. 1A is a schematic plan view showing a configuration of a semiconductor device according to a first embodiment of the present invention;

FIG. 1B is a schematic cross-sectional view taken along a line A-A′ of FIG. 1A;

FIG. 2 is a schematic cross-sectional view taken along a line B-B′ of FIG. 1A;

FIG. 3A is a schematic showing a configuration of a semiconductor device according to a modification of the first embodiment;

FIG. 3B is a schematic cross-sectional view taken along a line A-A′ of FIG. 3A;

FIG. 4A is a plan view indicative of an embodiment of a process in a manufacturing method of the semiconductor device according to the first embodiment;

FIG. 4B is a cross-sectional view taken along a line A-A′ of FIG. 4A;

FIG. 5A is a plan view indicative of an embodiment of a process in the manufacturing method of the semiconductor device according to the first embodiment;

FIG. 5B is a cross-sectional view taken along a line A-A′ of FIG. 5A;

FIG. 6A is a plan view indicative of an embodiment of a process in the manufacturing method of the semiconductor device according to the first embodiment;

FIG. 6B is a cross-sectional view taken along a line A-A′ of FIG. 6A;

FIG. 7 is a cross-sectional view taken along a line B-B′ of FIG. 6A;

FIG. 8A is a plan view indicative of an embodiment of a process in the manufacturing method of the semiconductor device according to the first embodiment;

FIG. 8B is a cross-sectional view taken along a line A-A′ of FIG. 8A;

FIG. 9A is a plan view indicative of an embodiment of a process in the manufacturing method of the semiconductor device according to the first embodiment;

FIG. 9B is a cross-sectional view taken along a line A-A′ of FIG. 9A;

FIG. 10A is a plan view indicative of an embodiment of a process in the manufacturing method of the semiconductor device according to the first embodiment;

FIG. 10B is a cross-sectional view taken along a line A-A′ of FIG. 10A;

FIG. 11A is a plan view indicative of an embodiment of a process in the manufacturing method of the semiconductor device according to the first embodiment;

FIG. 11B is a cross-sectional view taken along a line A-A′ of FIG. 11A;

FIG. 12 is a cross-sectional view taken along a line B-B′ of FIG. 11A;

FIG. 13A is a plan view indicative of an embodiment of a process in the manufacturing method of the semiconductor device according to the first embodiment;

FIG. 13B is a cross-sectional view taken along a line A-A′ of FIG. 13A;

FIG. 14A is a plan view indicative of an embodiment of a process in the manufacturing method of the semiconductor device according to the first embodiment;

FIG. 14B is a cross-sectional view taken along a line A-A′ of FIG. 14A;

FIG. 15A is a schematic diagram showing a configuration of a semiconductor device according to a second embodiment;

FIG. 15B is a cross-sectional view taken along a line B-B′ of FIG. 15A;

FIG. 16A is a plan view indicative of an embodiment of a process in the manufacturing method of the semiconductor device according to the second embodiment;

FIG. 16B is a cross-sectional view taken along a line A-A′ of FIG. 16A; and

FIG. 17 is a cross-sectional view taken along a line B-B′ of FIG. 16A.

### DETAILED DESCRIPTION OF THE EMBODIMENTS

Preferred embodiments of the present invention are explained below in detail with reference to the accompanying drawings. In the drawings explained below, configurations, sizes, and the number of constituent elements are different from those of actual products for easier understanding of these elements. In the following embodiments, an X-Y-Z coordinate system is set and the arrangement of respective configurations is described. In this coordinate system, a Z direction is a direction vertical to a surface of a silicon substrate, a Y direction as a first direction is a direction orthogonal to the Z direction, and an X direction as a second direction is a direction orthogonal to the Y direction in a horizontal surface to a surface of the silicon substrate.

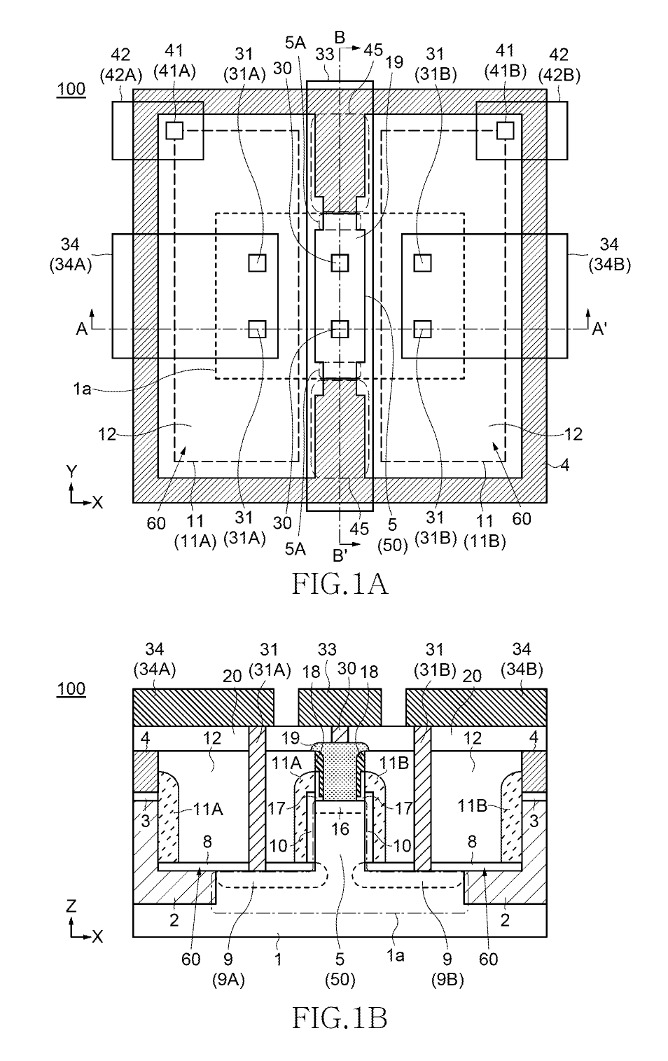

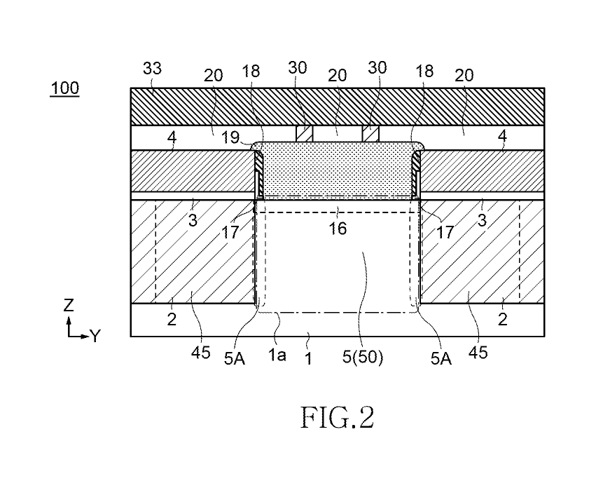

First, the semiconductor device 100 is described with reference to FIGS. 1A, 1B and 2. Incidentally, in FIG. 1A, for making arrangement conditions of respective constituent elements clear, wires located on an interlayer insulating film and contact plugs are illustrated in a transparent manner and only an outline thereof is shown.

Turning to FIGS. 1B and 2, the semiconductor device 100 according to the first embodiment includes a silicon substrate 1 as a representative semiconductor substrate. On an upper surface of the silicon substrate 1, an STI (Shallow Trench Isolation) 2 as an element isolation region is provided. A bottom surface and side surface of a lower part of the STI 2 contact the silicon substrate 1, and the silicon substrate 1 surrounded by the side surface of the lower part of the STI 2 is an active region 1a.

In a central part of the active region surrounded by the STI 2, one silicon pillar (semiconductor pillar) 5 is provided. The silicon pillar 5 is provided by arranging openings 60 at two ends in the X direction of the active region la. The silicon pillar 5 is a pillar semiconductor layer constituting a channel region of a unit transistor 50.

Ends 5A in the Y direction of the silicon pillar 5 respectively contact insulating pillars 45 that are integrated with the STI 2, and upper surfaces of the insulating pillars 45 have the same height as that of an upper surface of the silicon pillar 5. Similarly to the silicon pillar 5, the insulating pillars 45 are provided by arranging the openings 60 in the STI 2 as the element isolation region. In addition, next to the silicon pillar 5 and the insulating pillars 45, the opening 60 arranged on the left side in the X direction is respectively arranged integrally, so as to span the element isolation region and the active region 1a. The opening 60 arranged on the right side has the same configuration.

In an upper end and a lower part of the silicon pillar 5, impurity diffusion layers are respectively provided. A pillar upper diffusion layer 16 (first impurity diffusion layer) located in the upper end of the silicon pillar 5 is a diffusion layer as one source/drain region. A pillar lower diffusion layers 9 (9A and 9B) (second impurity diffusion layer) located in the lower part of the silicon pillar 5 are diffusion layers as the other source/drain region. A region of the silicon pillar 5 interposed between the pillar upper diffusion layer 16 and the pillar lower diffusion layer 9 functions as a channel region. In the first embodiment, the pillar lower diffusion layers 9 are respectively provided on both sides in the X direction of the silicon pillar 5, and the diffusion layer on the left side is called “pillar lower diffusion layer 9A” and the diffusion layer on the right side is called “pillar lower diffusion layer 9B”.

Insulating films 8 are formed on upper surfaces of the silicon substrate 1 exposed around the silicon pillar 5. The insulating films 8 cover the periphery of the silicon pillar 5 and reach the STI 2. Under the insulating films 8, the pillar lower diffusion layers 9 are arranged so as to be overlapped with the insulating films 8. Bottom surfaces of the pillar lower diffusion layers 9 are provided so as to become shallower than a bottom surface of the STI 2, and thus the adjacent pillar lower diffusion layers 9 in which the STI 2 is sandwiched therebetween are not conductive to each other.

A gate insulating film 10 is formed on side surfaces of the silicon pillar 5. Furthermore, through the gate insulating film 10, gate electrodes 11 (11A and 11B) are respectively arranged on two side surfaces opposed in the X direction of the silicon pillar 5. The gate electrodes 11 are provided on internal wall surfaces of the STI 2, on those of an insulating film 3 layered on an upper surface of the STI 2, and also on a part of those of a mask film 4 layered on an upper surface of the insulating film 3. In addition, the gate electrode 11A is located over the pillar lower diffusion layer 9A, and the gate electrode 11B is located over the pillar lower diffusion layer 9B. The gate insulating film 10 covers two side surfaces opposed in the X direction of the silicon pillar 5, extends in the Y direction, and is connected to the insulating film 8. By the gate insulating film 10, the gate electrodes 11 are electrically insulated from the channel region of the silicon pillar 5 and the pillar upper diffusion layer 16. Similarly, the gate electrodes 11 are electrically insulated from the pillar lower diffusion layers 9 by the insulating films 8.

On an upper surface of the STI 2 and the insulating pillars 45, the mask film 4 covering the insulating film 3 is formed. Furthermore, a first interlayer insulating film 12 is formed so as to cover the gate electrodes 11 and the insulating film 8. The first interlayer insulating film 12 is provided in a region surrounded by wall surfaces of the STI 2, the insulating film 3, and the mask film 4. On upper surfaces of the mask film 4 and the first interlayer insulating film 12, a second interlayer insulating film 20 is provided.

On an upper surface of the second interlayer insulating film 20, metal wires 33 and 34 (34A and 34B) are arranged. The metal wire 33 is connected to the pillar upper diffusion layer 16 of the silicon pillar 5 as the source/drain region of the unit transistor 50 via a silicon plug (a conductive plug) 19 surrounded by the first interlayer insulating film 12 and the gate electrodes 11, and two parallel metal contact plugs (conductive plugs) 30 that penetrate the second interlayer insulating film 20.

The silicon plug 19 is formed by implanting (diffusing) impurities such as arsenic into silicon and constitutes one source/drain region of the unit transistor 50 with the pillar upper diffusion layer 16. A sidewall film 18 and an insulating film 17 are arranged on a side surface of the silicon plug 19, and the silicon plug 19 is electrically insulated from the gate electrodes 11 by the sidewall film 18 and the insulating film 17.

The metal wires 34 are connected to the pillar lower diffusion layers 9 as the other source/drain region of the unit transistor 50 via metal contact plugs (conductive plugs) (31A and 31B) that penetrate the second interlayer insulating film 20, the first interlayer insulating film 12, and the insulating film 8. To explain this configuration in more detail, two metal contact plugs 31A that are connected to the metal wire 34A are connected to the pillar lower diffusion layer 9A, and two metal contact plugs 31B that are connected to the metal wire 34B are connected to the pillar lower diffusion layer 9B.

Turning to FIG. 1A, two openings 60 that span the STI 2 and the active region 1a surrounded by the STI 2 and are separated in the X direction are provided, and thus one rectangular silicon pillar 5 in a plan view is provided in the central part of the active region 1a. The silicon pillar 5 linearly extends in the Y direction, and constitutes the channel region of the unit transistor 50. Both end surfaces in the Y direction of the silicon pillar 5 match those in the Y direction of the active region 1a. That is, the silicon pillar 5 is arranged so as to longitudinally traverse the active region 1a.

The silicon pillar 5 has two side surfaces (first and third side surfaces) that are orthogonal to a longitudinal direction (the Y direction) and two side surfaces (second and fourth side surfaces) that are parallel to the longitudinal direction. One insulating pillar 45 (first insulating pillar) that is located on an upper side of FIG. 1A is provided while being in contact with the first side surface of the silicon pillar 5, and the other insulating pillar 45 (second insulating pillar) that is located on a lower side of FIG. 1A is provided while being in contact with the third side surface of the silicon pillar 5.

The silicon plug 19, the metal contact plug 30, and the metal wire 33 are arranged over the silicon pillar 5. In a plan view, the silicon pillar 5, the silicon plug 19, and the metal contact plug 30 are overlapped with each other and arranged in a region of the silicon plug 19. The metal wire 33 is arranged so as to extend in the Y direction.

One ends in the Y direction of the first and second insulating pillars 45 contact ends 5A in the Y direction of the silicon pillar 5, respectively, and the other ends in the Y direction of the first and second insulating pillars 45 are integrated with the STI 2 that surrounds the silicon pillar 5. The size (the cross-sectional area cut by a plane parallel to the silicon substrate 1) of the ends 5A of the silicon pillar 5 is set to be size in which it can be completely depleted, and made to be smaller than that of the central part of the silicon pillar 5. Accordingly, the size of the ends of the insulating pillars 45 that contact the ends 5A of the silicon pillar 5 is also made small. As described above, the narrow ends 5A formed near side surfaces of the silicon pillar 5 contacting the insulating pillars 45 function as a threshold voltage adjustment region for suppressing a reduction of a threshold voltage of the unit transistor 50 due to the insulating pillars 45.

The gate electrodes 11 are respectively arranged in two side surface parts in the X direction of the silicon pillar 5 and the insulating pillars 45, and constituted by the gate electrode 11A (first gate electrode) in one side surface part (second side surface) and the gate electrode 11B (second gate electrode) in the other side surface part (fourth side surface). The gate electrodes 11 are provided on the entire side surfaces of the silicon pillar 5, the insulating pillars 45, and the STI 2. In addition, the gate electrodes 11 provided on the side surfaces of the insulating pillars 45 and the STI 2 do not have a function as a gate electrode. However, for convenience of explanation, these elements are integrated with the gate electrodes 11 that are provided on side surfaces of the silicon pillar 5, and therefore described as the gate electrodes 11.

To the gate electrode 11A located over an upper part of the pillar lower diffusion layer 9A, a gate voltage is supplied from a signal wiring 42A via the gate electrode 11A located on a side surface part of the STI 2 and the gate electrode 11A located on side surface parts of the insulating pillars 45. Similarly, to the gate electrode 11B located over an upper part of the pillar lower diffusion layer 9B, the gate voltage is supplied from a signal wiring 42B via the gate electrode 11B located on a side surface part of the STI 2 and the gate electrode 11B located on side surface parts of the insulating pillars 45. That is, the gate electrodes 11 located on the side surface part of the STI 2 and the gate electrodes 11 located on the side surface parts of the insulating pillars 45 function as a wire for supplying the gate voltage to the gate electrodes 11 located on the side surface parts of the silicon pillar 5. As described above, the gate electrodes 11A and 11B function as a closed wire in the openings 60.

On an upper surface of the second interlayer insulating film 20, the two signal wirings 42 (42A and 42B) are arranged. The signal wiring 42 extend in the X direction so as not to be intersected with a metal wire 33, and are arranged in positions at least partially overlapped with metal contact plugs (conductive plugs) 41 (41A and 41B). An end of the signal wiring 42A is connected to the gate electrode 11A via the metal contact plug 41A that penetrates the second interlayer insulating film 20 and the first interlayer insulating film 12. Similarly, an end of the signal wiring 42B is also connected to the gate electrode 11B via the metal contact plug 41B.

The two metal contact plugs 41 (41A and 41B) are respectively provided in positions at least partially overlapped with the gate electrodes 11 (11A and 11B). The mask film 4 is formed over the STI 2 (more specially, on the insulating film 3 located on an upper surface of the STI 2), and the metal contact plugs 41 are connected to upper surface parts of the gate electrodes 11 located on a side surface of the mask film 4. With the STI 2, the mask film 4 formed over the STI 2 functions as a projection layer for increasing the height of the gate electrodes 11 and reducing the distance between the gate electrodes 11 and the signal wirings 42.

On the right and left sides in the X direction of the silicon pillar 5, the metal contact plugs 31 (31A and 31B) are arranged. The two metal contact plugs 31A are arranged on the left side in the X direction of the silicon pillar 5, and the two metal contact plugs 31B are arranged on the right side in the X direction of the silicon pillar 5. The metal wire 34A is arranged on the metal contact plugs 31A, and the metal wire 34B is arranged on the metal contact plugs 31B.

In FIG. 1A, the pillar lower diffusion layers 9, the metal contact plugs 31, and the metal contact plugs 41 are respectively arranged in regions on the right and left sides in the X direction of the silicon pillar 5. While the metal wires 34 and the signal wirings 42 are provided so as to be overlapped with these elements, the layout of each constituent component is not limited thereto and can be set arbitrary.

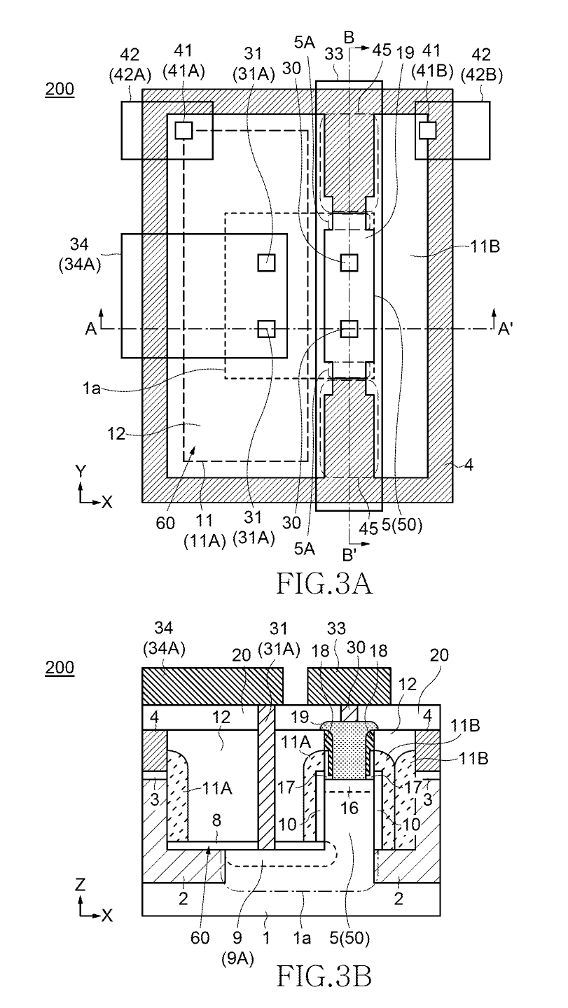

Turning to FIGS. 3A and 3B, only in a region on the left side in the X direction of the silicon pillar 5, the pillar lower diffusion layer 9, the metal contact plug 31, and the metal contact plug 41A are arranged, and the metal wire 34 and the signal wiring 42 can be provided so as to be overlapped with these elements, and the metal contact plug 41B and the gate electrode 11B that extends in the Y direction can be arranged in a region on the right side in the X direction of the silicon pillar 5. In addition, the cross-sectional view taken along a line B-B′ of FIG. 3A is omitted because it is the same as that of FIG. 2.

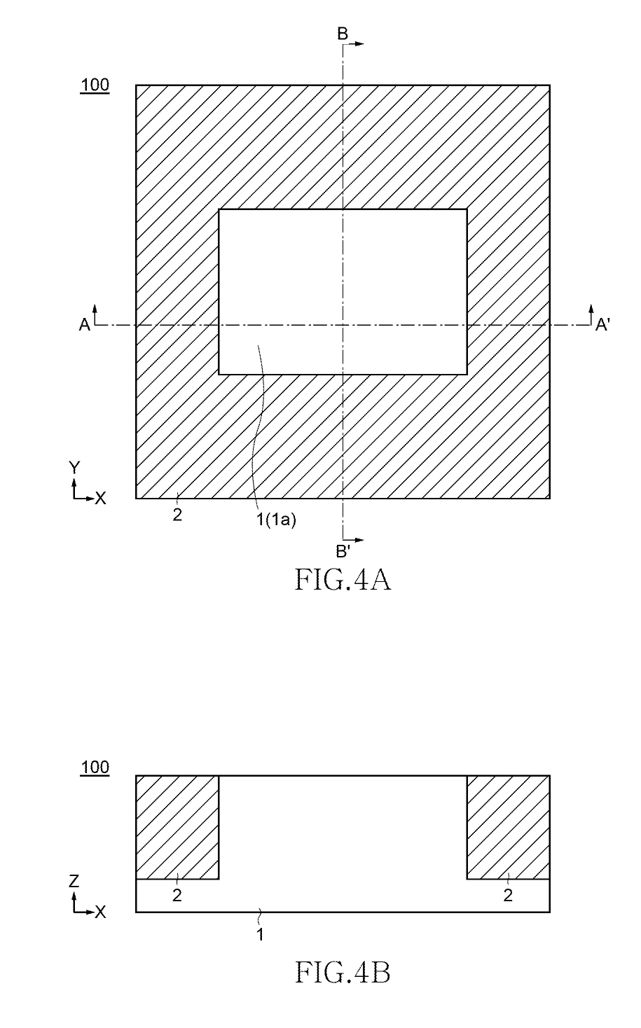

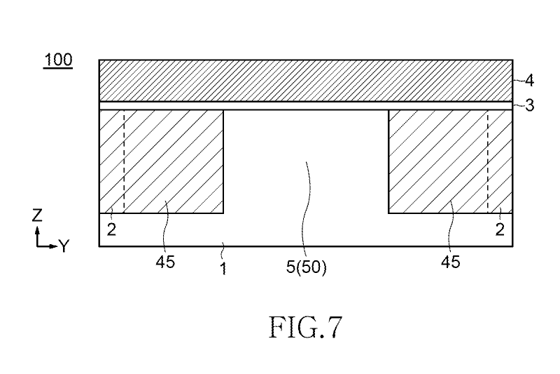

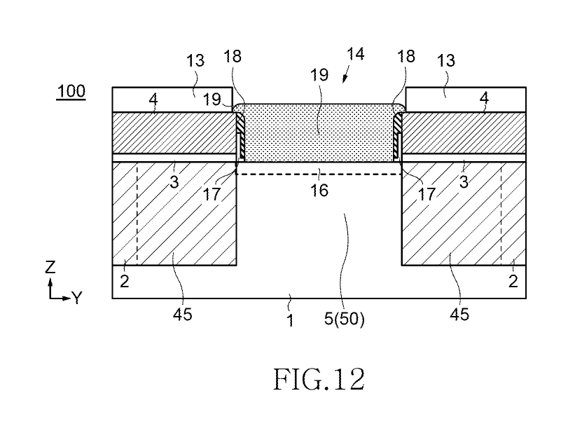

A manufacturing method of the semiconductor device 100 according to the first embodiment is described next in detail. In addition, each manufacturing process is described mainly with reference to FIGS. 4A, 4B, 5A, 5B, 6A, 6b, 8a, 8B, 9A, 9B, 10A, 10B, 11A, 11B, 13A, 13B, 14A and 14B. Explanations are arbitrarily complemented by FIG. 7 or 12 as necessary.

Turning to FIGS. 4A and 4B, in a manufacturing process of the semiconductor device 100, the STI 2 as an element isolation region is formed first in the silicon substrate 1. In a forming process of the STI 2, a groove (not shown) is formed first in the silicon substrate 1 by a photolithographic method and a dry etching process. Next, a thin silicon dioxide film (not shown) is formed on the entire surface of the silicon substrate 1 including an internal wall of the groove by a thermal oxidation method. Subsequently, a silicon dioxide film (SiO₂) is deposited on the entire surface of the silicon substrate 1 so as to fill the inside of the groove by a CVD (Chemical Vapor Deposition) process. An unnecessary silicon dioxide film on an upper surface of the silicon substrate 1 is then removed by a CMP (Chemical Mechanical Polishing) process and the silicon dioxide film is left only in the inside of the groove, thereby completing the STI 2. With this process, the silicon substrate 1 surrounded by the STI 2 is formed as the active region 1a.

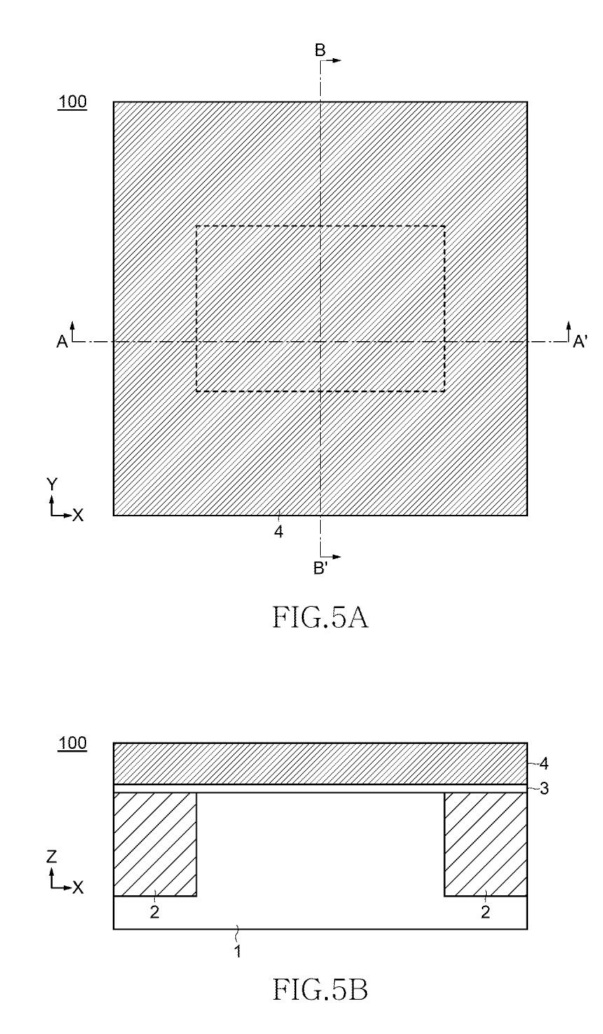

Next, turning to FIGS. 5A and 5B, the insulating film 3 which is made of a silicon dioxide film is formed on an upper surface of the silicon substrate 1 by a CVD process. The mask film 4 which is made of a silicon nitride film (SiN) is then deposited so as to have a thickness of 120 nm.

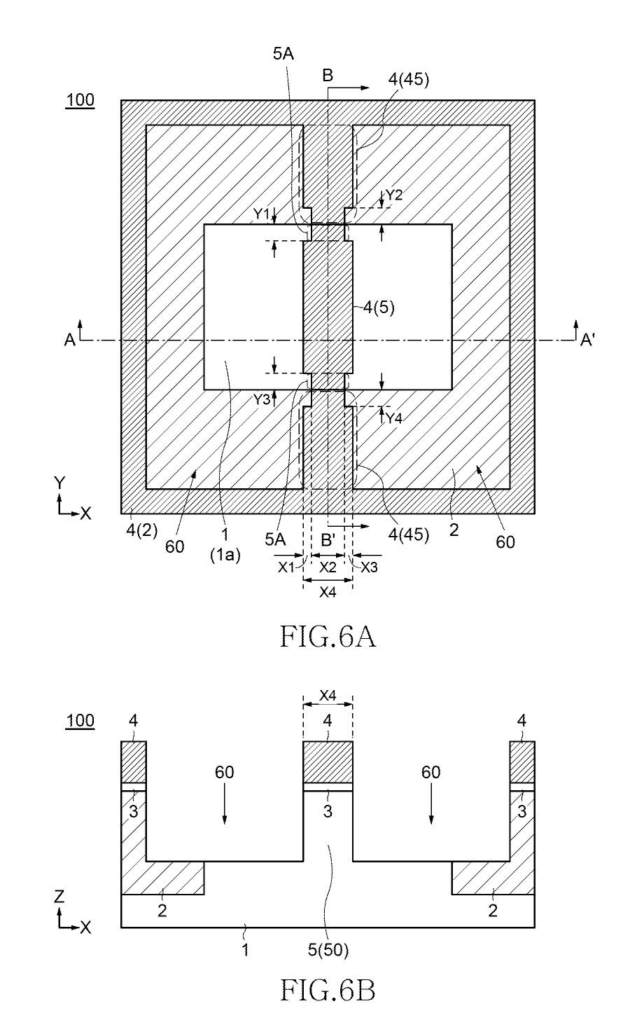

Next, turning to FIGS. 6A, 6B, and 7, opening patterns are formed in the insulating film 3 and the mask film 4 by a photolithographic method and a dry etching process. The opening patterns are formed so as to span from the STI 2 to the active region 1a. With this process, the silicon substrate 1 and the STI 2 are exposed in the opening patterns. Furthermore, the size of the mask film 4 left on an end in the Y direction of the exposed silicon substrate 1 is not uniform, that is, X1=X3=2.5 nm, X2=5 nm, X4=10 nm, Y1=Y3=2 nm, and Y2=Y4=8 nm are set, and a portion covering a boundary part between the silicon substrate 1 and the STI 2 is thinned.

Further, by using as a mask the mask film 4, the exposed silicon substrate 1 is dry-etched and then the openings 60 are formed to have a depth of 150 nm. With this process, there are formed the silicon pillar 5 as the channel region of the unit transistor 50 and the insulating pillars 45 for linking the gate electrodes 11 to the STI 2, and simultaneously, side surface parts of the STI 2 are exposed. A layout of the silicon pillar 5 and the insulating pillars 45 of this time is as shown in FIG. 6A.

In connection parts of the silicon pillar 5 and the insulating pillars 45, X2 as the widths of the ends 5A of the silicon pillar 5 are set to be 5 nm, Y1 and Y3 as the lengths are set to be 2 nm, and thereby the size (the cross-sectional area cut by a plane parallel to the silicon substrate 1) of the ends 5A of the silicon pillar 5 is set to a size in which the ends 5A of the silicon pillar 5 are completely depleted. At this time, the size in which the ends 5A of the silicon pillar 5 is completely depleted has a size equal to or less than that specified by X2 and Y1, and X2 and Y3. Therefore, it suffices that the size of X2 is 5 nm or less and each of the sizes of Y1 and Y3 is 2 nm or less. To explain this configuration in more detail, the sizes of Y2 and Y4 can have any value, and the sizes of X1 and X3 do not have to have the same value. That is, it suffices that the size of the ends 5A of the silicon pillar 5 is equal to or less than a specified value. Also, it suffices that, when the size of X4 as the width of the central part of the silicon pillar 5 is the same value as that of the size of X2, X1=X3=0 nm is set and X2 is not made to be smaller than X4.

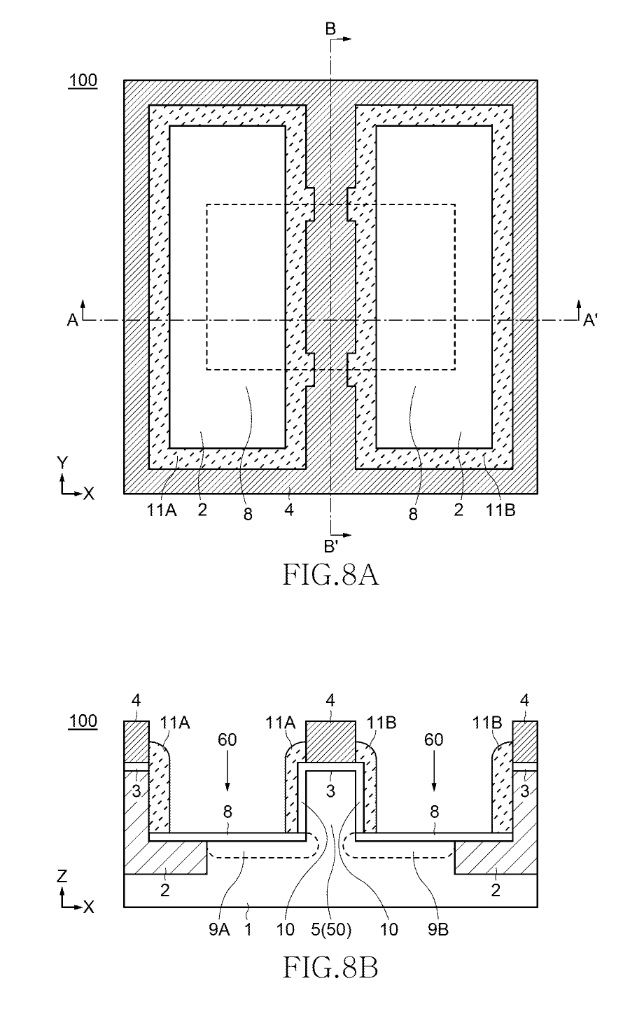

Next, turning to FIGS. 8A and 8B, the silicon substrate 1 is oxidized by a thermal oxidation method and the insulating films 8 having a thickness of 30 nm are formed in an exposed part of the silicon substrate 1. Next, the pillar lower diffusion layers 9 (9A and 9B) are formed under the insulating films 8 by an ion implantation process. In this example, one pillar lower diffusion layer 9A and the other pillar lower diffusion layer 9B are electrically isolated from each other. In addition, for example, arsenic (As) can be used as impurities to be implanted in a case of an N-type transistor. At this time, over the silicon pillar 5, the mask film 4 is left with a thickness of 100 nm and sufficiently thicker than the insulating films 8 that are formed on upper surfaces of the pillar lower diffusion layers 9. Therefore, ion is not implanted into an upper part of the silicon pillar 5 and thus a diffusion layer is not formed in the upper part of the silicon pillar 5.

Next, the gate insulating films 10 which are made of silicon dioxide films are formed on side surfaces of the silicon pillar 5 by a thermal oxidation method. Next, a polysilicon film (a polycrystalline silicon film) forming a gate electrode is formed on the entire surface of the silicon substrate 1 by a CVD process. The entire surface is then subjected to an etch-back process and the gate electrodes 11 (11A and 11B) are formed on side surfaces in the X direction of the silicon pillar 5.

When the gate electrode 11A is here formed on the side surface of the silicon pillar 5, the gate electrode 11A is simultaneously formed also onside surfaces of the insulating pillars 45 and the STI 2. The gate electrode 11A formed on the side surface of the silicon pillar 5 is connected to the gate electrode 11A formed on the side surface of the STI 2 via the gate electrode 11A formed on the side surfaces of the insulating pillars 45. The gate electrode 11B formed on the side surface of the silicon pillar 5 is similarly connected to the gate electrode 11B formed on the side surface of the STI 2 via the gate electrode 11B formed on the side surfaces of the insulating pillar 45. As described above, when the gate electrodes 11 extend to the side surfaces of the STI 2 from the silicon pillar 5, it is an essential requirement to connect the insulating pillars 45 to the silicon pillar 5.

Even if connection parts between the silicon pillar 5 and the insulating pillars 45 are narrowed, there is no problem in that the gate electrodes 11 are formed. This is caused by the fact that a polysilicon film having a superior step coverage property is used as materials of the gate electrodes 11. Even if the connection parts between the silicon pillar 5 and the insulating pillars 45 are narrowed to generate steps, disconnecting of the gate electrodes 11 does not occur. Therefore, the level of difficulty in forming the gate electrodes 11 is not changed at all.

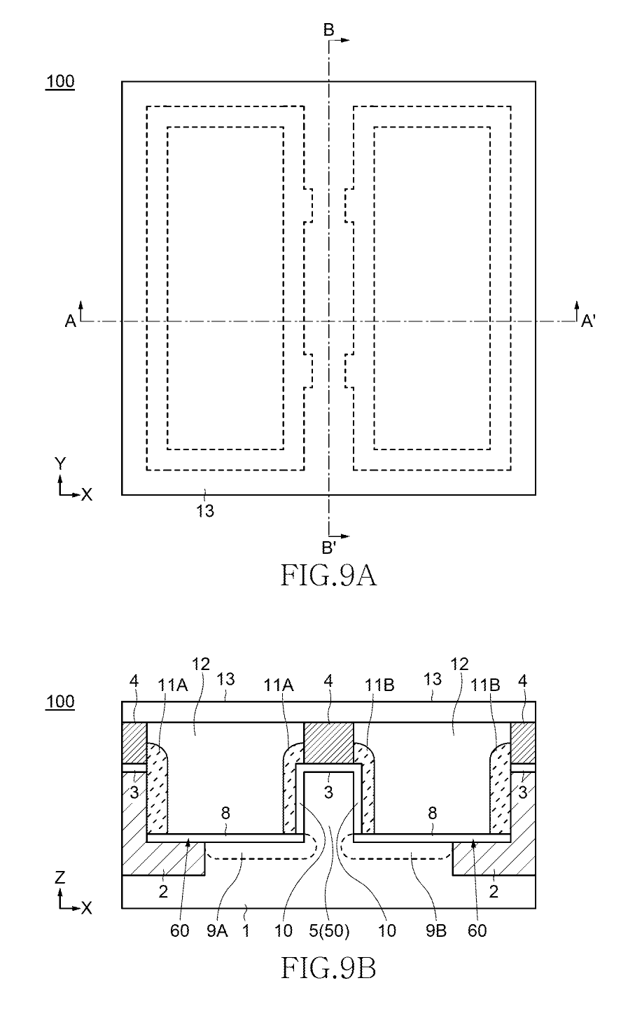

Next, turning to FIGS. 9A and 9B, by a CVD process, the first interlayer insulating film 12 which is made of a silicon dioxide film is formed so as to fill the openings 60. Next, by a CMP process, the first interlayer insulating film 12 is planarized so as to expose the mask film 4, and continuously the mask film 13 which is made of a silicon dioxide film is formed by a CVD process.

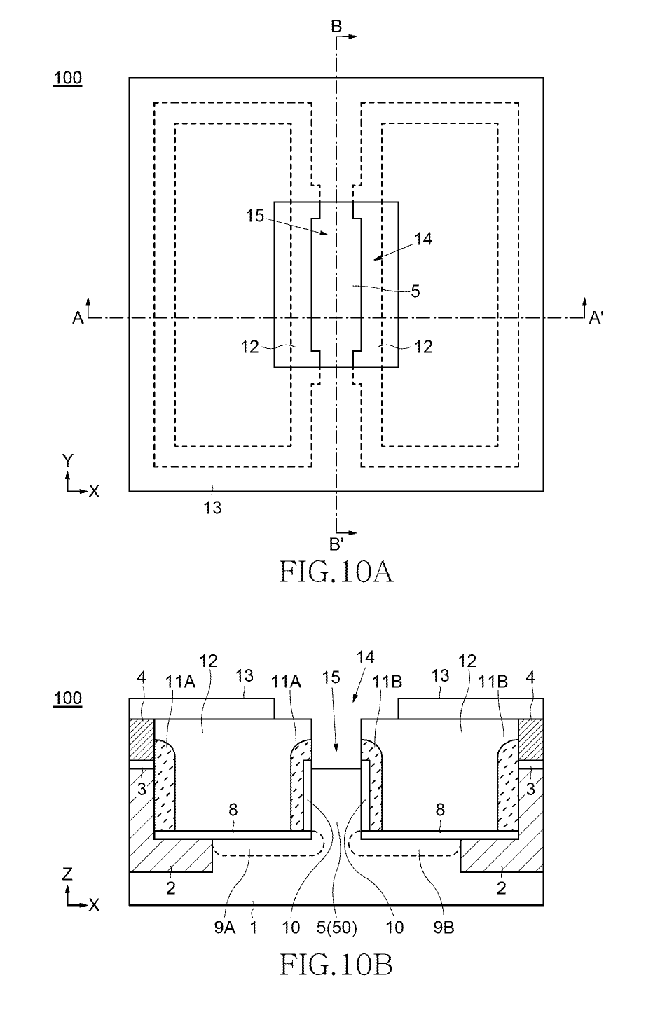

Next, turning to FIGS. 10A and 10B, the mask film 13 is partially removed by a photolithographic method and a dry etching process. As shown in FIG. 10A, only a part of the mask film 13 on which the silicon pillar 5 is arranged is selectively removed so as to form an opening 14. In the opening 14, the mask film 4 is exposed over the silicon pillar 5. Next, when the exposed mask film 4 is selectively removed by wet etching and the insulating film 3 is further removed, an opening 15 is formed over the silicon pillar 5. An upper surface of the silicon pillar 5 is exposed on a bottom surface of the opening 15, and the gate electrodes 11 (11A and 11B) are partially exposed on side surfaces thereof.

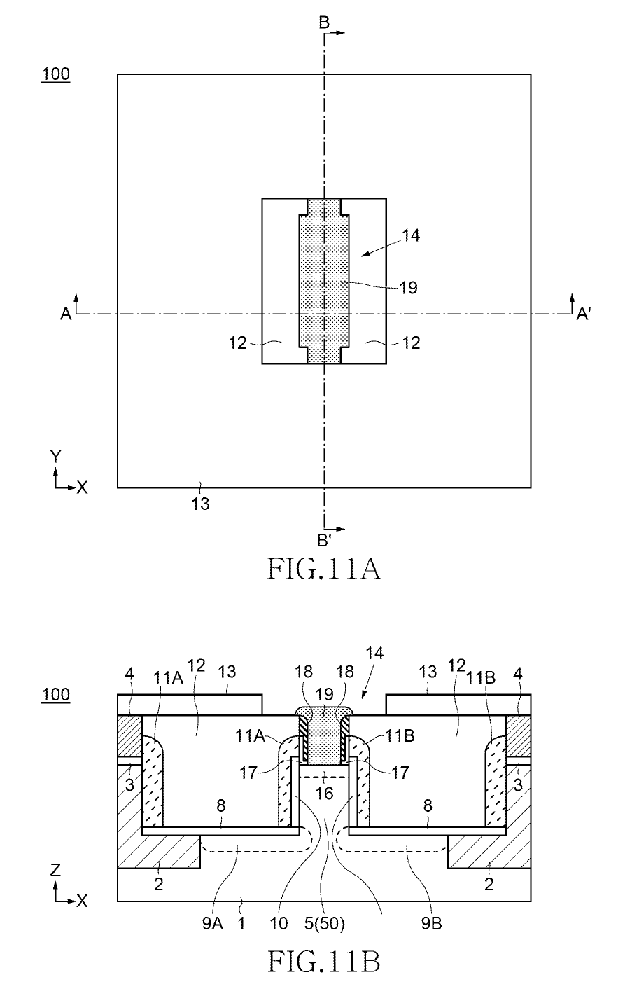

Next, turning to FIGS. 11A, 11B, and 12, the insulating film 17 which is made of a silicon dioxide film is formed on an internal wall of the opening 15 by a thermal oxidation method. Next, impurities (phosphorous (P) and arsenic (As) when an N-type transistor is manufactured) are ion-implanted into an upper part of the silicon pillar 5 from the opening 15 to form the pillar upper diffusion layer 16. Furthermore, a silicon nitride film is formed by a CVD process and then subjected to an etch-back process, thereby forming a sidewall film 18 on the internal wall of the opening 15. At the time of forming this sidewall film 18, the insulating film 17 formed on the upper surface of the silicon pillar 5 is also removed to expose the upper surface of the silicon pillar 5. At this time, the insulating film 17 is left under the sidewall film 18 and on the exposed surfaces of the gate electrodes 11 in the opening 15. The sidewall film 18 functions to secure insulation between the gate electrodes 11 and a silicon plug to be formed afterwards.

Next, by a selective epitaxial growth method, the silicon plug 19 is grown on the upper surface of the silicon pillar 5 so as to close the opening 15. Thereafter, in the case of manufacturing an N-type transistor, arsenic or the like is ion-implanted into the silicon plug 19 and the silicon plug 19 becomes an N-type conductive material. Thereby the silicon plug 19 is electrically connected to the pillar upper diffusion layer 16 that is formed on the upper part of the silicon pillar 5.

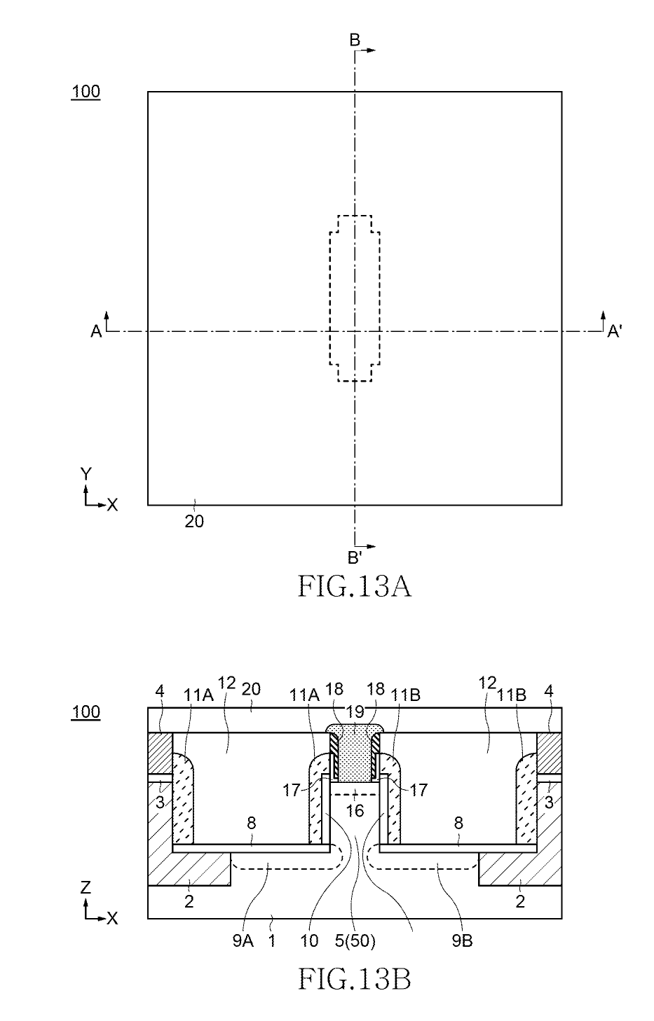

Next, turning to FIGS. 13A and 13B, by a CVD process, the second interlayer insulating film 20 which is made of a silicon dioxide film is formed so as to fill the opening 14. At this time, the mask film 13 is integrated with the second interlayer insulating film 20.

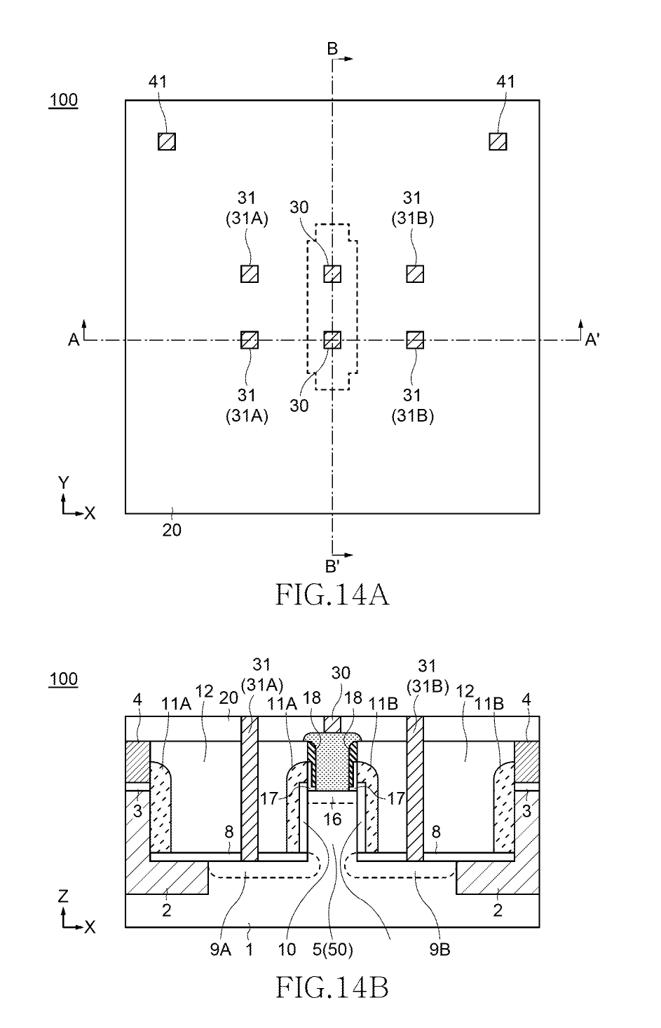

Next, turning to FIGS. 14A and 14B, the metal contact plugs 30 which are connected to the silicon plug 19, the metal contact plugs 31 (31A and 31B) which are connected to the pillar lower diffusion layers 9, and the metal contact plugs 41 which are connected to the gate electrodes 11 are formed. In a forming process of these contact plugs, contact holes are formed first in corresponding positions by a photolithographic method and a dry etching process. Next, by a CVD process, a metal film including tungsten (W), titanium nitride (TiN), and titanium (Ti) is formed so as to fill the inside of the contact holes and cover the second interlayer insulating film 20. Next, by a CMP process, the metal film formed on an upper surface of the second interlayer insulating film 20 is removed, thereby completing the metal contact plugs 30, 31, and 41.

Next, the signal wiring 42 and the metal wires 33 and 34 including tungsten and tungsten nitride (WN) are formed by a sputtering method. With this process, the semiconductor device 100 shown in FIG. 1 is completed. Also the semiconductor device 200 as a modification of the semiconductor device 100 can be formed similarly to the semiconductor device 100 only by changing the arrangement of constituent elements, and thus explanations of the manufacturing process thereof will be omitted.

According to the semiconductor device 100 of the first embodiment, the following effects can be achieved.

Firstly, regardless of the size of the central part of the silicon pillar 5, each of the ends 5A of the silicon pillar 5 contacting the insulating pillars 45 is set to have a size in which it is completely depleted. When the size mentioned above is used, the threshold voltage Vth in the end 5A is not reduced. Therefore, operations can be stabilized in the semiconductor device 100 as compared to a case where the end 5A is not set to have a size in which it is completely depleted.

Secondly, one ends in the Y direction of the insulating pillars 45 is respectively connected to the ends 5A in the Y direction of the silicon pillar 5 such that a side surface part of the silicon pillar 5 and a side surface part of the STI 2 are formed into one continuous plane surface, and simultaneously the other ends in the Y direction of the insulating pillars 45 are connected to the STI 2. Therefore, the gate electrodes 11 arranged on the side surfaces of the silicon pillar 5 are extended to the side surfaces of the STI 2. The signal wirings 42 and the gate electrodes 11 can be then connected by the metal contact plugs 41 arranged in the region of the STI 2. With the above configuration, the metal contact plugs 41 do not need to be provided near the silicon pillar 5. Therefore, it is possible to avoid short-circuit between the metal contact plugs 41 and the pillar lower diffusion layers 9 arranged under the silicon pillar 5 even when bottom parts of the metal contact plugs 41 reach the silicon substrate 1.

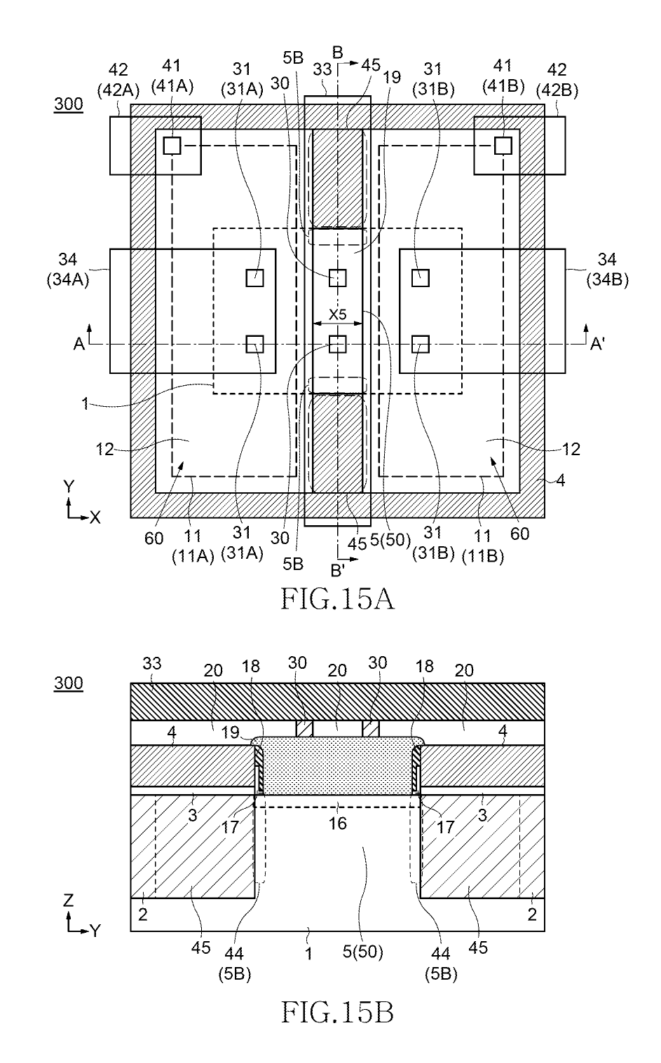

A second embodiment of the present invention is explained next in detail with reference to FIGS. 15A and 15B. The cross-sectional view taken along a line A-A′ of FIG. 15A is the same as that of FIG. 1B, and thus the following explanations are given with reference to FIG. 1B. In the following explanations, details common to those of the first embodiment will be omitted and only features of the second embodiment that are different from the first embodiment are described.

Turning to FIGS. 15B and 1B, pillar upper diffusion layer 16, pillar side surface diffusion layers 44 (third and fourth impurity diffusion layers), and pillar lower diffusion layers 9 (9A and 9B) are respectively provided in an upper end, side surface parts in the Y direction, and lower parts of the silicon pillar 5. The pillar upper diffusion layer 16 is a diffusion layer as one source/drain region. The pillar lower diffusion layers 9 (9A and 9B) are diffusion layers as the other source/drain region. Furthermore, pillar side surface diffusion layers 44 located on the side surface part (near first and third side surfaces) in the Y direction of the silicon pillar 5 are diffusion layers for locally increasing the threshold voltage Vth of the channel region of the silicon pillar 5. In other words, the pillar side surface diffusion layers 44 formed near the side surfaces of the silicon pillar 5 contacting the insulating pillars 45 function as a threshold voltage adjustment region for suppressing a threshold voltage of the unit transistor 50 from as reduced due to the insulating pillars 45. The depth of the pillar side surface diffusion layer 44 is equal to or more than 50% of the height of the silicon pillar 5.

Turning to FIG. 15A, ends 5B in the Y direction of the silicon pillar 5 respectively contact one ends in the Y direction of the insulating pillars 45. The other ends in the Y direction of the insulating pillars 45 are integrated with the STI 2 that surrounds the silicon pillar 5. In this example, the silicon pillar 5 has the same size as a width X5 of the central part and the ends 5B, and the insulating pillar 45 also has the same size as the width X5 of the silicon pillar 5, and these elements respectively extend in the Y direction. In addition, the width X5 of the silicon pillar 5 is set to have a size according to requirement specifications about the semiconductor device 300 regardless of the possibility of realization of the complete depletion.

A method for manufacturing the semiconductor device 300 according to the second embodiment is described next in detail.

In the manufacturing of the semiconductor device 300, the opening 15 is formed first over the silicon pillar 5 by a manufacturing process described in FIGS. 4A, 4B, 5A, 5B, 6A, 6b, 7, 8a, 8B, 9A, 9B, 10A and 10B. At this time, an upper surface of the silicon pillar 5 is exposed to a bottom surface of the opening 15.

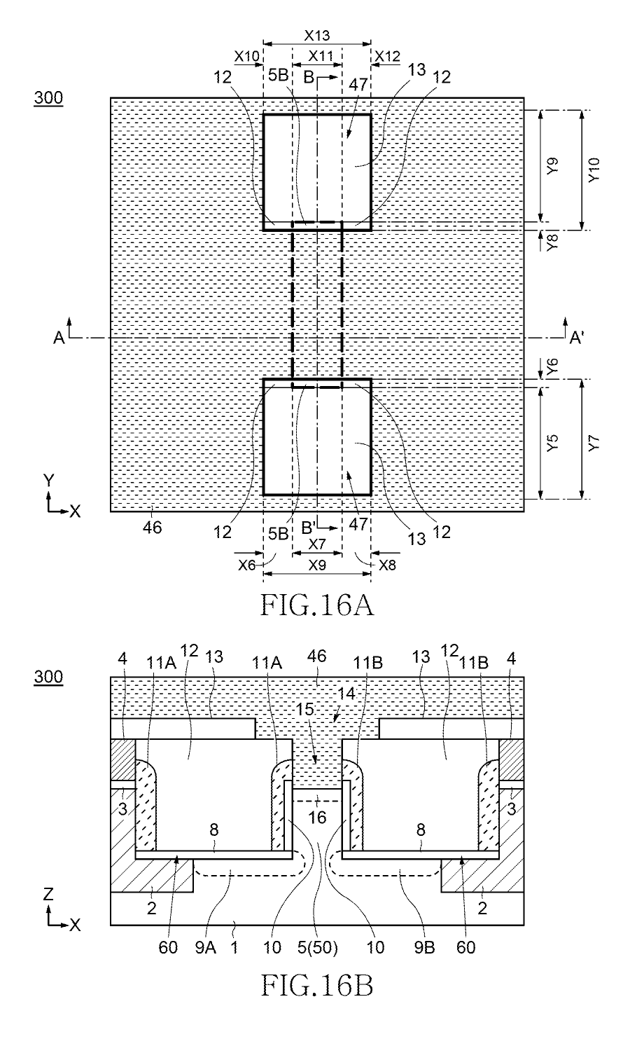

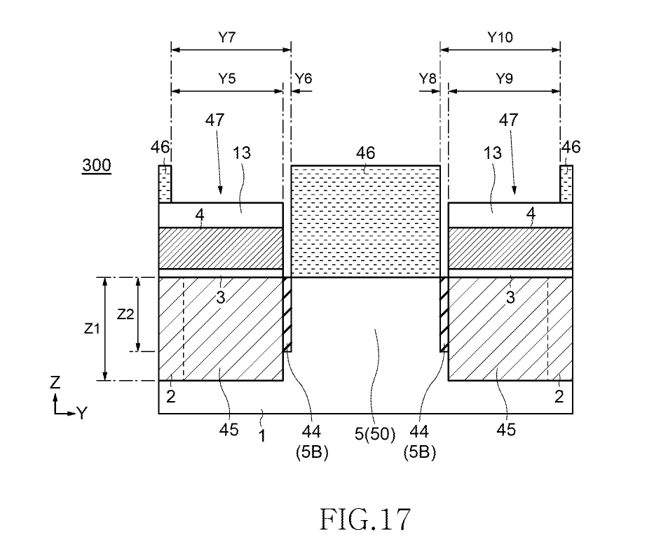

Next, turning to FIGS. 16A, 16B, and 17, by a spin-coating method, a photoresist 46 is formed so as to cover the upper surface of the silicon pillar 5. Next, by a photolithographic method, there is formed an opening 47 that partially exposes the upper surface of the silicon pillar 5 to the photoresist 46. The ends 5B in the Y direction of the silicon pillar 5, a part of the mask film 13, and a part of the first interlayer insulating films 12 are exposed to a bottom surface of the opening 47. The sizes of respective constituent elements constituting the bottom surfaces of the openings 47 are set to be X7=X11=10 nm, X6=X8=X10=X12=5 nm, X9=X13=20 nm, Y5=Y9=15 nm, Y6=Y8=5 nm, and Y7=Y10=20 nm. In this example, it suffices that Y6 and Y8 being the sizes of the ends 5B of the silicon pillar 5 are the values mentioned above. Furthermore, in the silicon pillar 5, when parts other than the ends 5B are covered by the photoresist 46, the sizes of the parts can have any value.

Next, by an ion implantation process, impurities are implanted into the bottom surfaces of the openings 47 to form the pillar side surface diffusion layers 44. For example, boron (B) and boron fluoride (BF₂) can be used as the impurities to be implanted in the case of an N-type transistor. At this time, impurity concentration of the pillar side surface diffusion layers 44 is set to be 1×10¹³ atoms/cm³, and a depth Z2 of the bottom surface thereof is set to be 90 nm. The depth Z2 is not limited to 90 nm, and it suffices that the depth Z2 is set to be deeper than 50% of a depth (a height) Z1 of the silicon pillar 5. Because the depth (the height) Z1 of the silicon pillar 5 according to the second embodiment is 150 nm, it suffices that the depth Z2 is set to be in a range of 75 nm to 150 nm.

Next, the insulating film 17 is formed on an internal wall of the opening 15 by the manufacturing process described in FIGS. 11A and 11B, and then constituent elements of the pillar upper diffusion layer 16 and so on are sequentially formed. With this process, the semiconductor device 300 shown in FIGS. 15A and 15B is completed.

According to the semiconductor device 300 of the second embodiment, the following effects can be achieved.

The pillar side surface diffusion layers 44 are provided on the ends 5B of the silicon pillar 5 contacting the insulating pillars 45. With this configuration, a reduction in the threshold voltage Vth due to a structure of the ends of the silicon pillar 5 is offset by locally increasing the threshold voltage in the pillar side surface diffusion layers 44. Therefore, degradation of the controllability of a gate potential can be suppressed. To explain this configuration in more detail, the pillar side surface diffusion layers 44 are locally provided on the ends 5B of the silicon pillar 5, and the threshold voltage Vth in the central part of the silicon pillar 5 is not increased. Accordingly, as compared to the case where the pillar side surface diffusion layers are not formed, operations can be stabilized in the semiconductor device 300. The second embodiment can also achieve the second effect described in the first embodiment.

It is apparent that the present invention is not limited to the above embodiments, but may be modified and changed without departing from the scope and spirit of the invention.

For example, in the above embodiments, there has been explained a silicon substrate, which is a typical example of semiconductor substrates; however, other types of semiconductor substrates can be also used in the present invention.

What is claimed is:

1. A semiconductor device comprising:
a semiconductor pillar projecting from a main surface of the semiconductor substrate, the semiconductor pillar having a first side surface extending in a first direction that is parallel to the main surface of the semiconductor substrate and a second side surface extending in a second direction crossing to the first direction and parallel to the main surface of the semiconductor substrate;
a first impurity diffusion layer formed in an upper portion of the semiconductor pillar;
a second impurity diffusion layer formed in the semiconductor substrate near a lower portion of the semiconductor pillar;
a first insulating pillar covering the first side surface of the semiconductor pillar; and
a first gate electrode covering the second side surface of the semiconductor pillar with an intervention of a first gate insulating film,
wherein a width in the first direction of the semiconductor pillar is narrowed at the first side surface.

2. The semiconductor device as claimed in claim 1, wherein
the first insulating pillar has a first side surface that is in contact with the first side surface of the semiconductor pillar and a second side surface that is substantially parallel to the second side surface of the semiconductor pillar, and
the first gate electrode further covers the second side surface of the first insulating pillar.

3. The semiconductor device as claimed in claim 2, wherein
the semiconductor pillar further has a third side surface that is parallel to the first side surface thereof,
the semiconductor device further comprises a second insulating pillar covering the third side surface of the semiconductor pillar, and
the width in the first direction of the semiconductor pillar is narrowed at the first and third side surfaces.

4. The semiconductor device as claimed in claim 3, wherein
the second insulating pillar has a first side surface that is in contact with the third side surface of the semiconductor pillar and a second side surface that is substantially parallel to the second side surface of the semiconductor pillar, and
the first gate electrode further covers the second side surface of the second insulating pillar.

5. The semiconductor device as claimed in claim 4, further comprising a first element isolation region having a side surface,
wherein the first gate electrode further covers the side surface of the first element isolation region.

6. The semiconductor device as claimed in claim 5, further comprising:
a first signal wiring; and
a first contact plug connecting the first signal wiring to the first gate electrode at a portion covering the side surface of the first element isolation region.

7. The semiconductor device as claimed in claim 4, wherein
the semiconductor pillar further has a fourth side surface that is parallel to the second side surface thereof, and
the semiconductor device further comprises a second gate electrode covering the fourth side surface of the semiconductor pillar with an intervention of a second gate insulating film.

8. The semiconductor device as claimed in claim 7, wherein
the first insulating pillar has a third side surface that is substantially parallel to the fourth side surface of the semiconductor pillar, and
the second gate electrode further covers the third side surface of the first insulating pillar.

9. The semiconductor device as claimed in claim 8, wherein
the second insulating pillar has a third side surface that is substantially parallel to the fourth side surface of the semiconductor pillar, and
the second gate electrode further covers the third side surface of the second insulating pillar.

10. The semiconductor device as claimed in claim 9, further comprising a second element isolation region having a side surface,
wherein the second gate electrode further covers the side surface of the second element isolation region.

11. The semiconductor device as claimed in claim 10, further comprising:
a second signal wiring; and
a second contact plug connecting the second signal wiring to the second gate electrode at a portion covering the side surface of the second element isolation region.

12. The semiconductor device as claimed in claim 1, further comprising:
a third signal wiring connected to the first impurity diffusion layer; and
a fourth signal wiring connected to the second impurity diffusion layer.

13. A semiconductor device comprising:
a semiconductor pillar projecting from a main surface of the semiconductor substrate;
a first impurity diffusion layer formed in an upper portion of the semiconductor pillar;
a second impurity diffusion layer formed in the semiconductor substrate near a lower portion of the semiconductor pillar;
a first insulating pillar that is in contact with the semiconductor pillar; and
a first gate electrode covering a first side surface of the semiconductor pillar with an intervention of a first gate insulating film,
wherein the semiconductor pillar includes a first portion and a second portion located between the first portion and the first insulating pillar, the second portion has a different impurity concentration from the first portion.

14. The semiconductor device as claimed in claim 13, wherein
the first insulating pillar has a first side surface that is substantially parallel to the first side surface of the semiconductor pillar, and
the first gate electrode further covers the first side surface of the first insulating pillar.

15. The semiconductor device as claimed in claim 14, further comprising a second insulating pillar that is in contact with the semiconductor pillar,
wherein the semiconductor pillar further includes a third portion located between the first portion and the second insulating pillar, the third portion has a different impurity concentration from the first portion.

16. The semiconductor device as claimed in claim 15, wherein the third portion has substantially the same impurity concentration as the second portion.

17. The semiconductor device as claimed in claim 15, further comprising a first element isolation region having a side surface,
wherein the first gate electrode further covers the side surface of the first element isolation region.

18. The semiconductor device as claimed in claim 17, further comprising:
a first signal wiring; and
a first contact plug connecting the first signal wiring to the first gate electrode at a portion covering the side surface of the first element isolation region.

19. The semiconductor device as claimed in claim 15, wherein
the semiconductor pillar further includes a second side surface opposite to the first side surface thereof,
the first insulating pillar further includes a second side surface opposite to the first side surface thereof,
the second insulating pillar further includes a second side surface opposite to the first side surface thereof,
the semiconductor device further comprises a second gate electrode covering the second side surface of the semiconductor pillar with an intervention of a second gate insulating film, and
the second gate insulating film further covers the second side surface of each of the first and second insulating pillars.

20. The semiconductor device as claimed in claim 19, further comprising a second element isolation region having a side surface,
wherein the second gate electrode further covers the side surface of the second element isolation region,
the semiconductor device further comprises a second signal wiring and a second contact plug connecting the second signal wiring to the second gate electrode at a portion covering the side surface of the second element isolation region.
